(19) United States
(12) Patent Application Publication
(10) Pub. No.: US 2021/0272995 A1
(43) Pub. Date: Sep. 2, 2021

(54) IMAGING ELEMENT AND ELECTRONIC APPARATUS

(71) Applicant: SONY SEMICONDUCTOR SOLUTIONS CORPORATION, KANAGAWA (JP)

(72) Inventors: YOSHIAKI MASUDA, KANAGAWA (JP); YUTAKA OOKA, KANAGAWA (JP); SOTETSU SAITO, KANAGAWA (JP); TAKAHIRO KAMEI, KANAGAWA (JP); WATARU ISHII, KANAGAWA (JP); NAOKI SATO, KANAGAWA (JP); SHINICHI MATSUOKA, KANAGAWA (JP); HIROKAZU YOSHIDA, KANAGAWA (JP)

(21) Appl. No.: 17/250,355

(22) PCT Filed: Jun. 14, 2019
(86) PCT No.: PCT/JP2019/023618

§ 371 Date: Jan. 8, 2021

(30) Foreign Application Priority Data
Jul. 19, 2018 (JP) 2018-136049

(51) Int. Cl. H01L 27/146

(52) U.S. Cl. CPC H01L 27/14618; H01L 27/14645; H01L 27/1464; H01L 27/14627; H01L 27/14636; H01L 27/14621

(57) ABSTRACT

An imaging element according to an embodiment of the present disclosure includes: a sensor substrate having a light-receiving region in which a plurality of light-receiving elements are arranged and a peripheral region provided around the light-receiving region; a sealing member disposed to be opposed to one surface of the sensor substrate; a resin layer that attaches the sensor substrate and the sealing member to each other; and an excavated part provided in the peripheral region of the one surface of the sensor substrate, and in which the resin layer is embedded, with the resin layer having one or a plurality of gaps inside the excavated part in a plan view.

### TECHNICAL FIELD

The present disclosure relates to, for example, an imaging element with an optical sensor configured as a chip-scale package, and an electronic apparatus including the imaging element.

### BACKGROUND ART

A wafer chip scale package (Wafer Chip Scale Package; WCSP) structure has been proposed as a simple package method for an optical sensor. The WCSP structure involves performing processing of adhering a silicon substrate and a glass substrate to each other, and the adhesive structure needs to be appropriately addressed. For example, PTL 1 discloses an imaging element provided with an excavated part in the vicinity of four corners of an outer peripheral region outside an effective pixel region of a sensor substrate in a structure in which the sensor substrate, a seal resin, and a sealing glass are stacked in order. A seal resin is embedded in the excavated part to thereby improve share strength of a joint part and thus to achieve an improvement in reliability.

### CITATION LIST

### Patent Literature

PTL 1: Japanese Unexamined Patent Application Publication No. 2013-41878

### SUMMARY OF THE INVENTION

As described above, the imaging element is required to improve the reliability.

It is desirable to provide an imaging element and an electronic apparatus that make it possible to improve reliability.

An imaging element according to an embodiment of the present disclosure includes: a sensor substrate having a light-receiving region in which a plurality of light-receiving elements are arranged and a peripheral region provided around the light-receiving region; a sealing member disposed to be opposed to one surface of the sensor substrate; a resin layer that attaches the sensor substrate and the sealing member to each other; and an excavated part provided in the peripheral region of the one surface of the sensor substrate, and in which the resin layer is embedded, with the resin layer having one or a plurality of gaps inside the excavated part in a plan view.

An electronic apparatus according to an embodiment of the present disclosure includes, as an imaging element, the imaging element according to an embodiment of the present disclosure.

In the imaging element and the electronic apparatus of respective embodiments of the present disclosure, the excavated part is provided in the peripheral region of the sensor substrate having the light-receiving region in which the plurality of light-receiving elements are arranged. The resin layer that attaches the sensor substrate and the sealing member to each other is embedded in the excavated part, and the one or the plurality of gaps are provided in the resin layer embedded in the excavated part in a plan view. This reduces application of local stress to the excavated part.

According to the imaging element and the electronic apparatus of the respective embodiments of the present disclosure, the excavated part is provided in the peripheral region of the sensor substrate to which the sealing member is attached with the resin layer interposed therebetween, and the one or the plurality of gaps are provided in the resin layer embedded in the excavated part in a plan view. This reduces application of local stress to the excavated part, enabling prevention of breakage of the resin layer. Thus, it is possible to improve reliability.

It is to be noted that the effects described here are not necessarily limitative, and may be any of the effects described in the present disclosure.

### BRIEF DESCRIPTION OF THE DRAWINGS

FIG. 1 is a schematic cross-sectional view of an example of a configuration of a main part of an imaging element according to an embodiment of the present disclosure.

FIG. 2 is a schematic cross-sectional view of an overall configuration of the imaging element illustrated in FIG. 1.

FIG. 3 is a schematic plan view of the overall configuration of the imaging element illustrated in FIG. 1.

FIG. 4A is a schematic cross-sectional view of another example of positions of gaps in the imaging element illustrated in FIG. 1.

FIG. 4B is a schematic cross-sectional view of another example of the positions of the gaps in the imaging element illustrated in FIG. 1.

FIG. 4C is a schematic cross-sectional view of another example of the positions of the gaps in the imaging element illustrated in FIG. 1.

FIG. 5 is a schematic cross-sectional view of another example of the configuration of the main part of the imaging element illustrated in FIG. 1.

FIG. 6A is a schematic cross-sectional view of another example of a position of a gap in the imaging element illustrated in FIG. 5.

FIG. 6B is a schematic cross-sectional view of another example of the position of the gap in the imaging element illustrated in FIG. 5.

FIG. 6C is a schematic cross-sectional view of another example of positions of gaps in the imaging element illustrated in FIG. 5.

FIG. 7A is an explanatory schematic cross-sectional view of a manufacturing method of the imaging element illustrated in FIG. 1.

FIG. 7B is a schematic cross-sectional view of a step subsequent to FIG. 7A.

FIG. 7C is a schematic cross-sectional view of a step subsequent to FIG. 7B.

FIG. 8A is a schematic cross-sectional view of another example of a shape of an excavated part of the imaging element illustrated in FIG. 1.

FIG. 8B is a schematic cross-sectional view of another example of the shape of the excavated part of the imaging element illustrated in FIG. 1.

FIG. 8C is a schematic cross-sectional view of another example of the shape of the excavated part of the imaging element illustrated in FIG. 1.

FIG. 8D is a schematic cross-sectional view of another example of the shape of the excavated part of the imaging element illustrated in FIG. 1.

FIG. 9 is a schematic cross-sectional view of a configuration of a main part of an imaging element as a comparative example.

FIG. 10 illustrates fracture strength characteristics of Comparative Examples 1 and 2 and the embodiment.

FIG. 11 illustrates white turbidity strength characteristics of Comparative Examples 1 and 2 and the embodiment.

FIG. 12 is a block diagram illustrating a configuration of the imaging element illustrated in FIG. 1.

FIG. 13 is a functional block diagram illustrating an example of an electronic apparatus (camera) using the imaging element illustrated in FIG. 12.

FIG. 14 is a block diagram depicting an example of a schematic configuration of an in-vivo information acquisition system.

FIG. 15 is a view depicting an example of a schematic configuration of an endoscopic surgery system.

FIG. 16 is a block diagram depicting an example of a functional configuration of a camera head and a camera control unit (CCU).

FIG. 17 is a block diagram depicting an example of schematic configuration of a vehicle control system.

FIG. 18 is a diagram of assistance in explaining an example of installation positions of an outside-vehicle information detecting section and an imaging section.

### MODES FOR CARRYING OUT THE INVENTION

In the following, description is given in detail of an embodiment of the present disclosure with reference to the drawings. The following description is merely a specific example of the present disclosure, and the present disclosure should not be limited to the following aspects. Moreover, the present disclosure is not limited to arrangements, dimensions, dimensional ratios, and the like of each component illustrated in the drawings. It is to be noted that the description is given in the following order.
1. Embodiment (An example in which a black layer is provided on a light-shielding layer provided on an organic photoelectric conversion layer)

1-1. Configuration of Imaging Element

1-2. Configuration of Excavated Part and Vicinity Thereof

1-3. Workings and Effects
2. Application Examples

### 1. EMBODIMENT

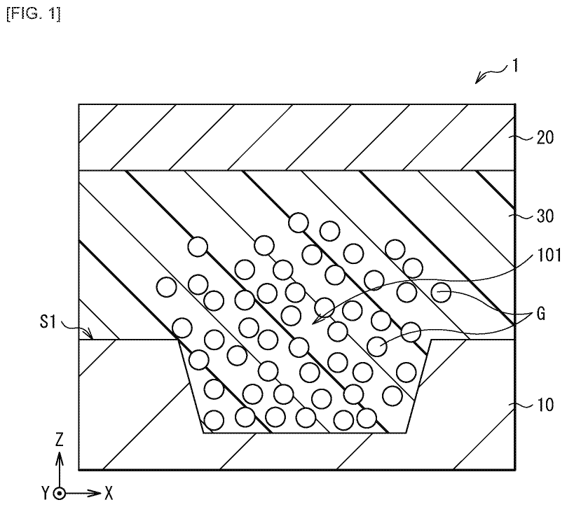

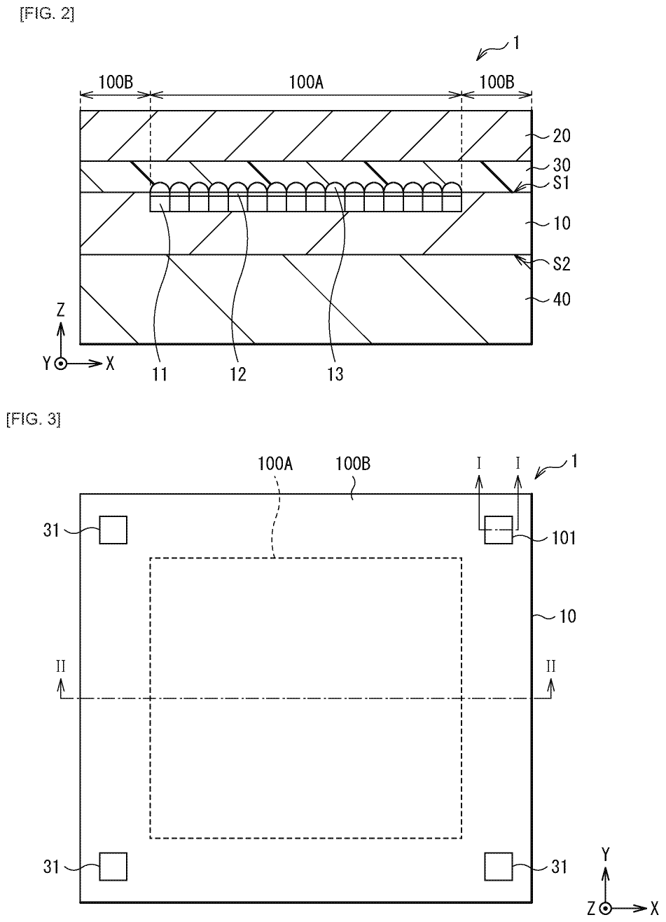

FIG. 1 schematically illustrates a cross-sectional configuration of a main part of an imaging element (an imaging element 1) according to an embodiment of the present disclosure. FIG. 2 schematically illustrates an overall cross-sectional configuration of the imaging element 1 illustrated in FIG. 1. FIG. 3 schematically illustrates an overall planar configuration of the imaging element 1 illustrated in FIG. 1. FIG. 1 illustrates a portion of a cross-sectional configuration taken along a line I-I indicated in FIG. 3, and FIG. 2 illustrates a cross-sectional configuration taken along a line II-II indicated in FIG. 3. The imaging element 1 is, for example, a backside illumination type (backside light-reception type) CCD (Charge Coupled Device) image sensor or CMOS (Complementary Metal Oxide Semiconductor) image sensor, etc. The imaging element 1 of the present embodiment is an imaging element having a so-called WCSP structure, that is packaged by attaching a sealing member 20 onto a sensor substrate 10, in which a plurality of light-receiving elements 11 are arranged, with a resin layer 30 interposed therebetween. In the imaging element 1, a back surface (a surface S1; one surface) of the sensor substrate 10 is provided with an excavated part 101. The resin layer 30 is embedded in the excavated part 101, and a plurality of gaps G are configured to be formed inside the excavated part 101 in a plan view.

### (1-1. Configuration of Imaging Element)

The imaging element 1 has a configuration in which the sensor substrate 10, the resin layer 30, and the sealing member 20 are stacked in this order. The sensor substrate 10 has a light-receiving region 100A in which the plurality of light-receiving elements 11 are arranged in an array state on side of the back surface (surface S1), and a peripheral region 100B in the vicinity thereof. The peripheral region 100B is provided with the excavated part 101 in the vicinity of each of four corners, for example, as described above. The resin layer 30 is embedded in the excavated part 101, and the plurality of gaps G are formed in the resin layer 30 embedded in the excavated part 101. For example, a support substrate 40 is attached to a front surface (a surface S2; the other surface) of the sensor substrate 10.

The sensor substrate 10 has the light-receiving region 100A and the peripheral region 100B in the periphery thereof. The light-receiving region 100A includes, on the side of the back surface (surface S1), the light-receiving elements 11 that selectively detect light in mutually different wavelength regions for each unit pixel P (see, e.g., FIG. 12) to perform photoelectric conversion. The light-receiving element 11 includes, for example, a photodiode or the like; the light-receiving element 11 is embedded and formed in the back surface (surface S1) of the sensor substrate 10, for example, and constitutes a light-receiving surface. The peripheral region 100B is provided with, for example, a peripheral circuit (a peripheral circuit section 130) including a row scanner 131, a horizontal selector 133, a column scanner 134, and a system controller 132 (see, e.g., FIG. 12).

A color filter 12 is provided on the light-receiving element 11, for example. As for the color filter 12, color filters of red (R), green (G) and blue (B), which are three primary colors, are arranged in a Bayer manner, for example, in the light-receiving region 100A.

An on-chip lens 13 is further provided over the light-receiving element 11, with the color filter 12 interposed therebetween. The on-chip lens 13 is provided for condensing incident light on the light-receiving element 11, and is configured by a material having light-transmissivity. Examples of the material having light-transmissivity include a transparent resin material such as an acrylic material, silicon oxide (SiO), silicon nitride (SiN), and silicon oxynitride (SiON). The on-chip lens 13 is configured by a monolayer film including one of those described above, or a stacked film including two or more thereof.

It is to be noted that another layer may be provided between the light-receiving element 11 and the on-chip lens 13; for example, an optical filter such as an anti-reflection layer or an infrared cut filter may be provided on the color filter 12.

For example, a pixel transistor is formed and a multilayer wiring layer is provided on side of the front surface (surface S2 on side opposite to the light-receiving surface) of the sensor substrate 10.

The sealing member 20 is a member having light-transmissivity for sealing the light-receiving region 100A of the sensor substrate 10. As the sealing member 20, for example, a glass substrate is used, but this is not limitative. For example, an acrylic resin substrate, a sapphire substrate, or the like may be used.

The resin layer 30 is provided for attaching the sensor substrate 10 and the sealing member 20 to each other in a region including at least the light-receiving region 100A. A resin material with optical characteristics (refractive index, extinction coefficient, etc.) being prioritized is selected for the resin layer 30, for example, to enable the light-receiving element 11 to favorably receive light incident on the imaging element 1. Examples of the material of the resin layer 30 include a siloxane-based resin material, an acrylic-based resin material, a styrene-based resin material, and an epoxy-based resin material. Alternatively, a configuration may be adopted, in which an inorganic film such as SiO (silicon oxide) or SiN (silicon nitride) is used, instead of the resin of the organic material, as the resin layer 30 to join the sensor substrate 10 and the sealing member 20 together.

The support substrate 40 is provided for supporting the sensor substrate 10. A signal processing circuit or the like that performs signal processing on a pixel signal outputted from the sensor substrate 10 may be formed, for example, in the support substrate 40.

### (1-2. Configuration of Excavated Part and Vicinity Thereof)

As described above, in the imaging element 1 of the present embodiment, the back surface (surface S1; one surface) of the sensor substrate 10 to be attached to the sealing member 20 is provided with the excavated part 101 in the peripheral region 100B.

As illustrated in FIG. 3, for example, four excavated parts 101 are provided in respective vicinities of the four corners of the peripheral region 100B, for example, and are formed in respective similar cross-sectional shapes. Specifically, as illustrated in FIG. 1, the excavated part 101 is formed as a recess part having a trapezoidal cross-sectional shape with a tapered surface narrowing in a depth direction. Examples of the size of the excavated part 101 include 100 μm×100 μm with a depth of 5 μm, but this is not limitative. The resin layer 30 is embedded in the excavated part 101.

In the present embodiment, the plurality of gaps G are formed in the resin layer 30 embedded inside the excavated part 101 in a plan view, and the excavated part 101 and the resin layer 30 in the vicinity thereof have rigidity lower than that of the surrounding.

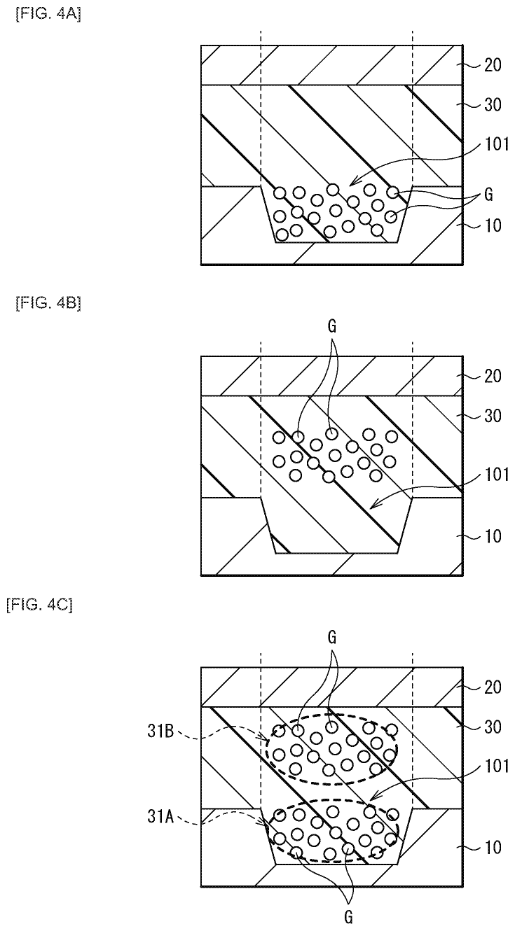

The gap G formed in the resin layer 30 has a nanobubble structure containing a plurality of bubbles each having a mean hole diameter of 30 nm to 300 nm, for example. As illustrated in FIG. 1, the plurality of gaps G formed as the nanobubble structure are preferably provided inside and above the excavated part 101 in a side view, but this is not limitative. For example, as illustrated in FIG. 4A, the plurality of gaps G may be formed only in the recess part formed as the excavated part 101. Alternatively, as illustrated in FIG. 4B, the plurality of gaps G may be formed only above the excavated part 101. Alternatively, as illustrated in FIG. 4C, the plurality of gaps G may be formed separately in two region 31A and 31B, i.e., inside the recess part formed as the excavated part 101 and above the recessed part.

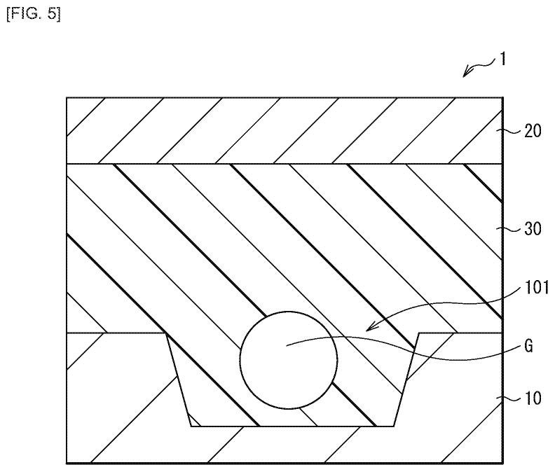

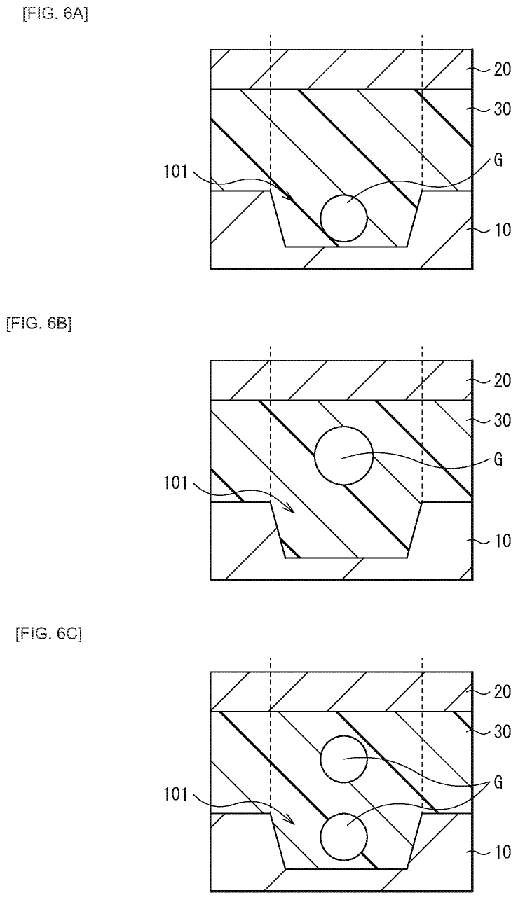

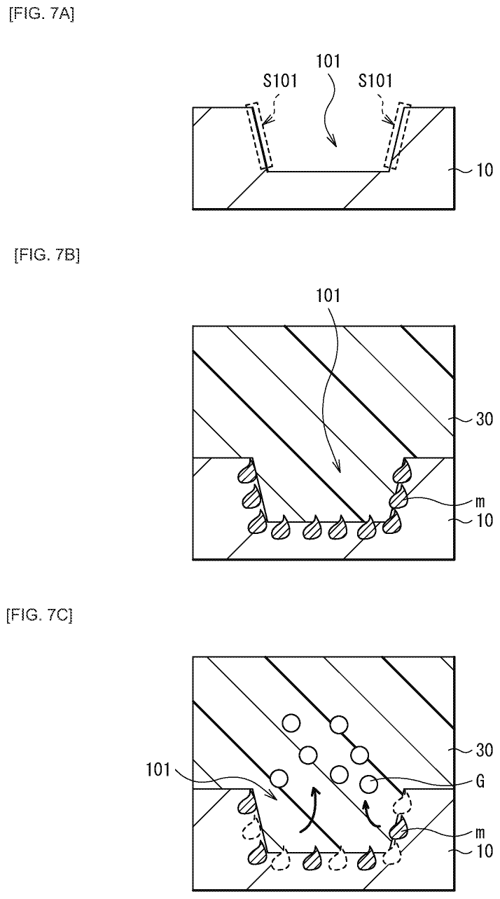

In addition, as illustrated in FIG. 5, the gap G formed in the resin layer 30 has a microbubble structure having a mean hole diameter of 10 μm to 30 μm, and may be formed as a single bubble, for example. As illustrated in FIG. 4, the gap G formed as the microbubble structure is preferably provided at positions hanging inside and above the excavated part 101 in a side view, but this is not limitative. For example, as illustrated in FIG. 6A, the gap G may be formed to be accommodated in the recessed part formed as the excavated part 101. Alternatively, as illustrated in FIG. 6B, the gap G may be formed above the excavated part 101. Alternatively, as illustrated in FIG. 6C, the gap G may be formed one by one inside and above the recessed part formed as the excavated part 101.

That is, it is sufficient for one or a plurality of gaps G to be formed inside the excavated part 101 and in the resin layer 30 in the vicinity thereof, and the size, the shape, and the number thereof do not particularly matter.

Further, air is usually contained in the gap G, but this is not limitative. For example, the gap G may be filled with a material softer than the resin layer 30, such as rubber or a resin material having lower strength.

The gap G as described above may be formed, for example, as follows.

First, in order to cause a location for formation of the excavated part 101 to open, a region other than the location for formation of the excavated part 101 on the sensor substrate 10 is patterned using a photoresist. Subsequently, for example, dry etching is performed to form the excavated part 101 at a position where the photoresist is opened, and thereafter ashing, for example, is performed to remove a side surface (a surface S101) after the etching, as illustrated in FIG. 7A.

Next, as illustrated in FIG. 7B, gaseous components such as moisture are adsorbed to the side surface and a bottom surface that constitute the excavated part 101, and thereafter a resin material serving as the resin layer 30 is applied onto the entire surface of the sensor substrate 10. At this time, the resin material is applied to fill the excavated part 101 as well.

Subsequently, as illustrated in FIG. 7C, performing heating treatment on the sensor substrate 10 to thereby cause the moisture or the like adsorbed to the side surface and the bottom surface of the excavated part 101 to be vaporized, thus forming the one or the plurality of gaps G inside the excavated part 101 and in the vicinity thereof.

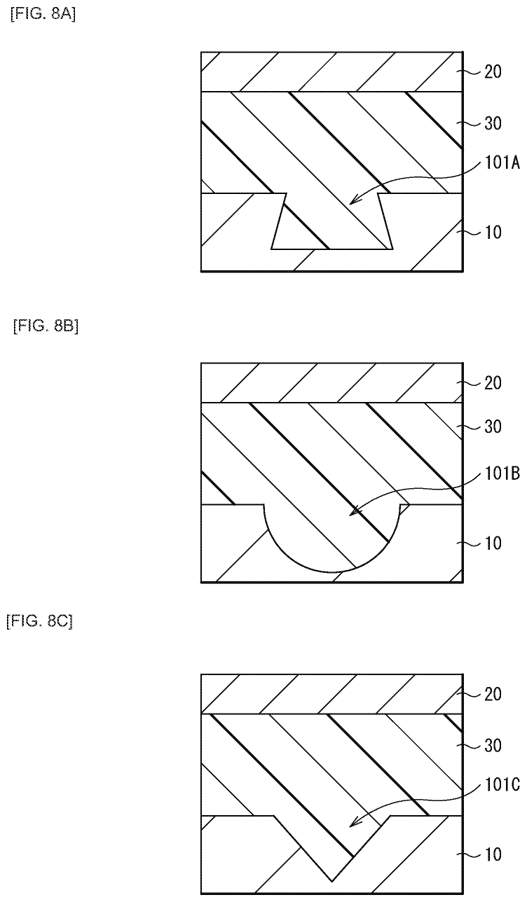

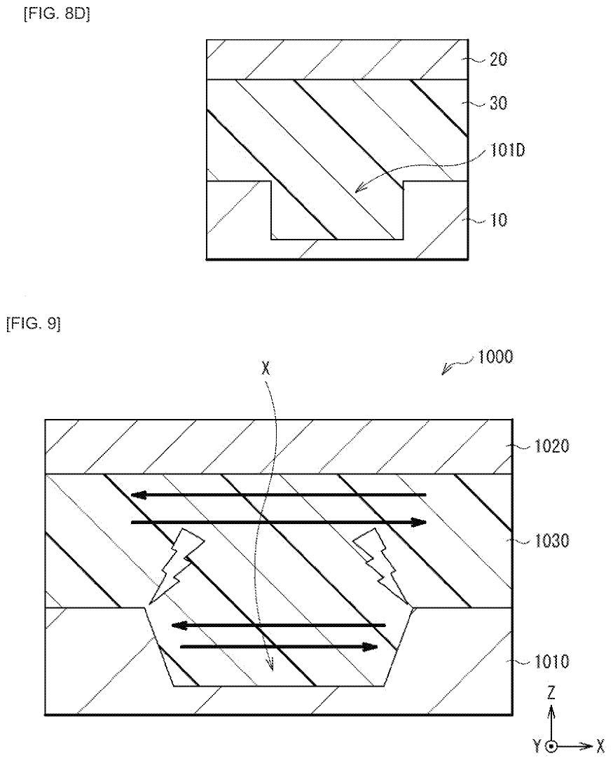

It is to be noted that the shape of the excavated part 101 is not limited. FIG. 1 exemplifies the excavated part 101 having a trapezoidal cross-sectional shape with a tapered surface narrowing in the depth direction, but this is not limitative; for example, shapes as illustrated in FIG. 8A to FIG. 8D may be adopted.

For example, the excavated part 101 may be a recessed part having a trapezoidal cross-sectional shape with a tapered surface expanding in the depth direction, as in an excavated part 101A illustrated in FIG. 8A. In addition, the excavated part 101 may be a recessed part having a concave curved cross-sectional shape, as in an excavated part 101B illustrated in FIG. 8B. Further, the excavated part 101 may be a recessed part having a triangular cross-sectional shape with a tapered surface having an apex, as in an excavated part 101C illustrated in FIG. 8C. Furthermore, the excavated part 101 may be a recessed part having a rectangular cross-sectional shape, in which the side surface is substantially orthogonal to the surface 51 of the sensor substrate 10, as in an excavated part 101D illustrated in FIG. 8D.

### (1-3. Workings and Effects)

As described above, the WCSP structure involves performing processing of attaching a silicon substrate and a glass substrate to each other, and the adhesive structure needs to be appropriately addressed. For this reason, a method has been proposed that provides excavated parts in respective vicinities of four corners of an outer peripheral region outside an effective pixel region of a sensor substrate, and fills the excavated parts with a seal resin to attach the silicon substrate and the glass substrate to each other to thereby improve share strength of a joint part.

FIG. 9 schematically illustrates a cross-sectional configuration of an excavated part X of an imaging element (an imaging element 1000) having the above-described structure and the periphery thereof. In a structure in which the excavated part X provided in a sensor substrate 1010 is filled with a seal resin as in the imaging element 1000, a resin layer 1030 provided between the sensor substrate 1010 and a sealing member 1020 differs in an amount of change in a planar direction (e.g., an X-axis direction) due to contraction or expansion between the inside of the excavated part X and other regions, as indicated by arrows. Such a difference leads to a possibility that the resin layer 1030 may break due to local stress being applied to corner portions of the excavated part X, for example.

As a method for solving this issue, methods are conceivable to allow the inside of the excavated part X to be a cavity so as not to provide a step in the resin layer 1030, or to fill the inside of the excavated part X as well as the excavated part X and a region thereabove with a material different from those for other regions. However, in the above-described methods, there is a possibility that adhesive strength between the sensor substrate 1010 and the resin layer 1030 may be lowered, or that the manufacturing steps may be complicated.

In contrast, in the imaging element 1 of the present embodiment, the formation of the one or the plurality of gaps G in the excavated part 101, or in the resin layer 300 in the vicinity thereof, provided in the peripheral region 100B of the sensor substrate 10 allows the stress applied to the corner portions or the like of the excavated part 101 due to the contraction or expansion of the resin layer 30 to be relieved.

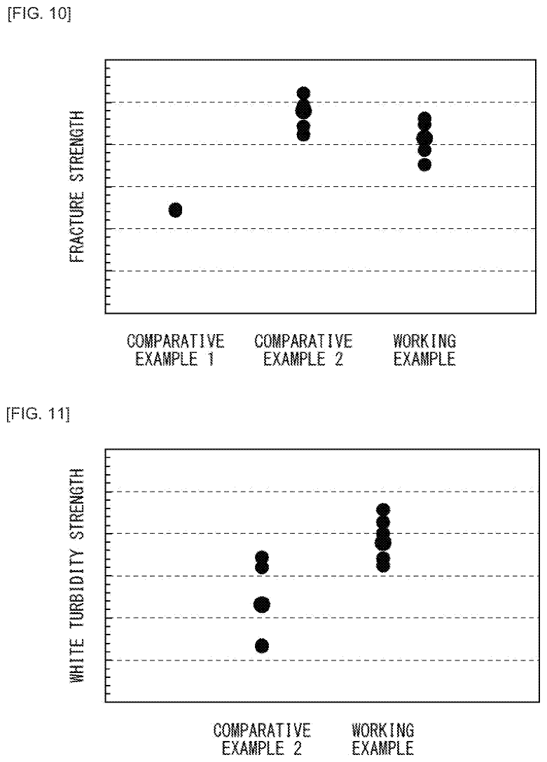

FIG. 10 illustrates fracture strength characteristics of respective resin layers (e.g., resin layer 30) in an imaging element (Comparative Example 1) having no excavated part in the peripheral region of the sensor substrate, in the imaging element 1000 (Comparative Example 2) having the above-described structure, and in the imaging element 1 (embodiment) of the present embodiment. In comparison with Comparative Example 1 having no excavated part, Comparative Example 2 and the embodiment each having the excavated part obtain equivalent fracture strength regardless of the internal structure of the excavated part.

FIG. 11 illustrates white turbidity strength characteristics of the respective resin layers (e.g., resin layer 30) in the imaging element 1000 (Comparative Example 2) having the above-described structure and the imaging element 1 (embodiment) of the present embodiment. The white turbidity strength refers to a strength at which the resin starts to become white and turbid upon application of stress, and indicates that the higher the strength becomes, the less likely a photographed or shot image is influenced, for example. In comparison with Comparative Example 2 in which the excavated part X is completely filled with the resin layer 1030, in the embodiment in which the gap G is provided in the excavated part 101, it is possible to confirm an improvement in the white turbidity strength.

As described above, in the imaging element 1 of the present embodiment, the one or the plurality of gaps G are provided in the resin layer 30 embedded in the excavated part 101 provided in the peripheral region 100B of the sensor substrate 10. This makes it possible to reduce the application of local stress to the corner portions or the like of the excavated part 101, and thus to prevent breakage of the resin layer 30. Thus, it becomes possible to improve reliability.

In addition, in the present embodiment, generation of white turbidity due to the breakage or the like of the resin layer 30 is reduced, thus making it also possible to improve a manufacturing yield and a design property.

### 2. APPLICATION EXAMPLES

### Application Example 1

FIG. 12 is a block diagram illustrating an overall configuration of the imaging element 1 described in the foregoing embodiment. The imaging element 1 is a CMOS imaging sensor. The imaging element 1 includes a pixel section 1a as an imaging area on the sensor substrate 10, and includes, for example, the peripheral circuit section 130 configured by the row scanner 131, the horizontal selector 133, the column scanner 134, and the system controller 132 in a peripheral region of the pixel section 1a.

The pixel section 1a includes, for example, a plurality of unit pixels P (corresponding to the imaging element 1) arranged two-dimensionally in matrix. To the unit pixels P, for example, pixel drive lines Lread (specifically, row selection lines and reset control lines) are wired on a pixel-row basis, and vertical signal lines Lsig are wired on a pixel-column basis. The pixel drive line Lread transmits a drive signal for reading of a signal from the pixel. One end of the pixel drive line Lread is coupled to an output terminal corresponding to each row in the row scanner 131.

The row scanner 131 is configured by a shift register, an address decoder, etc. The row scanner 131 is, for example, a pixel driver that drives the respective unit pixels P in the pixel section 1a on a row-unit basis. Signals outputted from the respective unit pixels P in the pixel row selectively scanned by the row scanner 131 are supplied to the horizontal selector 133 via the respective vertical signal lines Lsig. The horizontal selector 133 is configured by an amplifier, a horizontal selection switch, etc., that are provided for each vertical signal line Lsig.

The column scanner 134 is configured by a shift register, an address decoder, etc. The column scanner 134 sequentially drives the respective horizontal selection switches in the horizontal selector 133 while scanning the respective horizontal selection switches in the horizontal selector 133. As a result of the selective scanning by the column scanner 134, signals of the respective pixels to be transmitted via the respective vertical signal lines Lsig are sequentially outputted to horizontal signal lines 135, and are transmitted to the outside of the sensor substrate 10 through the horizontal signal lines 135.

A circuit part configured by the row scanner 131, the horizontal selector 133, the column scanner 134, and the horizontal signal lines 135 may be formed directly on the sensor substrate 10, or may be arranged in an external control IC. Alternatively, the circuit part may be formed on another substrate coupled with use of a cable, etc.

The system controller 132 receives a clock, data instructing an operation mode, etc., that are supplied from the outside of the sensor substrate 10. The system controller 132 also outputs data such as internal information of the imaging element 1. The system controller 132 further includes a timing generator that generates various timing signals, and performs drive control of the peripheral circuit such as the row scanner 131, the horizontal selector 133, and the column scanner 134 on the basis of the various timing signals generated by the timing generator.

### Application Example 2

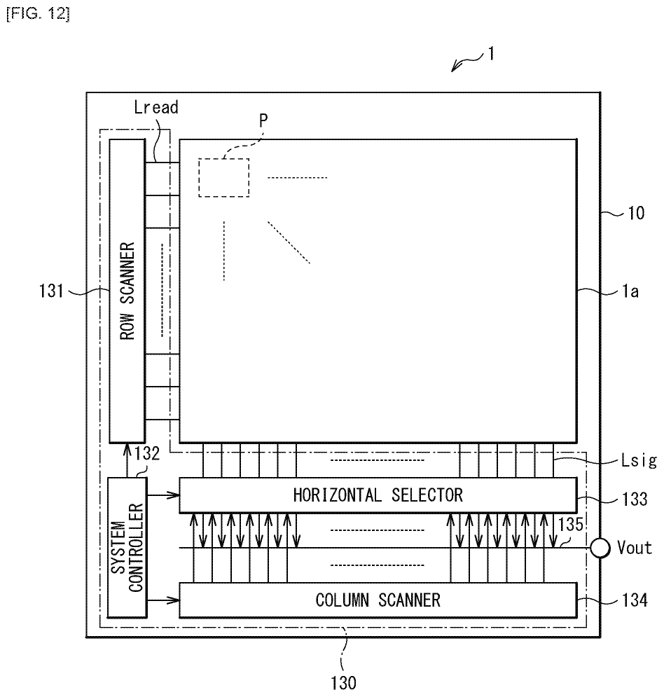

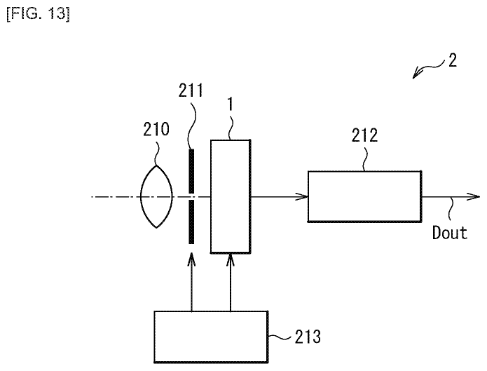

The above-described imaging element 1 is applicable to any type of electronic apparatus having an imaging function, for example, a camera system such as a digital still camera and a video camera, and a mobile phone having the imaging function. FIG. 13 illustrates an outline configuration of an electronic apparatus 2 (camera) as an example thereof. This electronic apparatus 2 is, for example, a video camera that is able to photograph a still image or shoot a moving image. The electronic apparatus 2 includes, for example, the imaging element 1, an optical system (optical lens) 310, a shutter device 311, a drive section 313 that drives the imaging element 1 and the shutter device 311, and a signal processing section 312.

The optical system 310 guides image light (incident light) from a subject to the pixel section 1a in the imaging element 1. The optical system 310 may be configured by a plurality of optical lenses. The shutter device 311 controls periods of light irradiation and light shielding with respect to the imaging element 1. The drive section 313 controls a transfer operation of the imaging element 1 and a shutter operation of the shutter device 311. The signal processing section 312 performs various types of signal processing on a signal outputted from the imaging element 1. An image signal Dout after the signal processing is stored in a storage medium such as a memory, or outputted to a monitor, etc.

Further, the above-described imaging element 1 is also applicable to electronic apparatuses (a capsule type endoscope 10100 and a mobile body such as a vehicle) described below.

### Application Example 3

### <Example of Practical Application to In-Vivo Information Acquisition System>

Further, the technology according to an embodiment of the present disclosure (present technology) is applicable to various products. For example, the technology according to an embodiment of the present disclosure may be applied to an endoscopic surgery system.

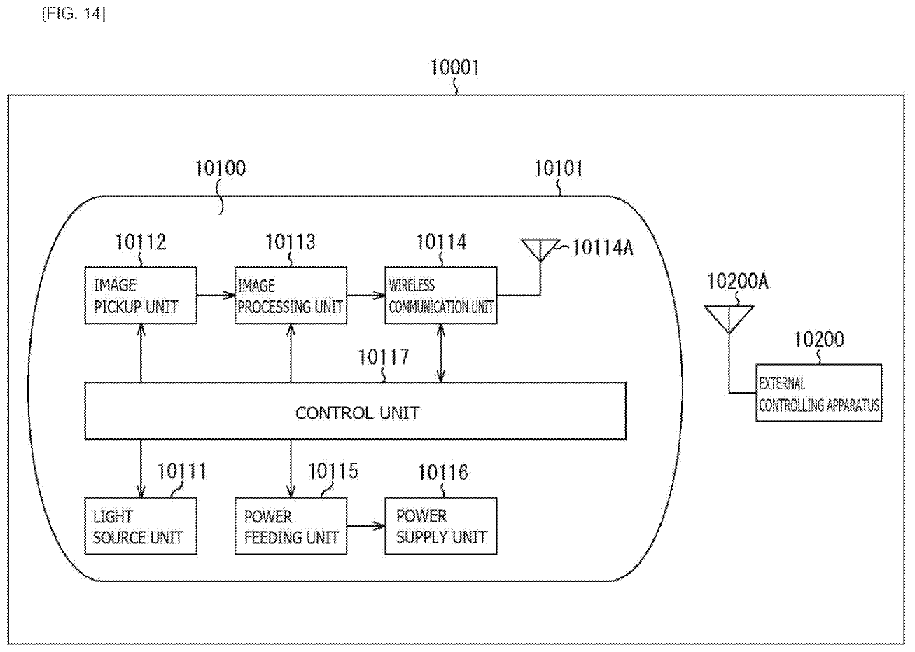

FIG. 14 is a block diagram depicting an example of a schematic configuration of an in-vivo information acquisition system of a patient using a capsule type endoscope, to which the technology according to an embodiment of the present disclosure (present technology) can be applied.

The in-vivo information acquisition system 10001 includes the capsule type endoscope 10100 and an external controlling apparatus 10200.

The capsule type endoscope 10100 is swallowed by a patient at the time of inspection. The capsule type endoscope 10100 has an image pickup function and a wireless communication function and successively picks up an image of the inside of an organ such as the stomach or an intestine (hereinafter referred to as in-vivo image) at predetermined intervals while it moves inside of the organ by peristaltic motion for a period of time until it is naturally discharged from the patient. Then, the capsule type endoscope 10100 successively transmits information of the in-vivo image to the external controlling apparatus 10200 outside the body by wireless transmission.

The external controlling apparatus 10200 integrally controls operation of the in-vivo information acquisition system 10001. Further, the external controlling apparatus 10200 receives information of an in-vivo image transmitted thereto from the capsule type endoscope 10100 and generates image data for displaying the in-vivo image on a display apparatus (not depicted) on the basis of the received information of the in-vivo image.

In the in-vivo information acquisition system 10001, an in-vivo image imaged a state of the inside of the body of a patient can be acquired at any time in this manner for a period of time until the capsule type endoscope 10100 is discharged after it is swallowed.

A configuration and functions of the capsule type endoscope 10100 and the external controlling apparatus 10200 are described in more detail below.

The capsule type endoscope 10100 includes a housing 10101 of the capsule type, in which a light source unit 10111, an image pickup unit 10112, an image processing unit 10113, a wireless communication unit 10114, a power feeding unit 10115, a power supply unit 10116 and a control unit 10117 are accommodated.

The light source unit 10111 includes a light source such as, for example, a light emitting diode (LED) and irradiates light on an image pickup field-of-view of the image pickup unit 10112.

The image pickup unit 10112 includes an image pickup element and an optical system including a plurality of lenses provided at a preceding stage to the image pickup element. Reflected light (hereinafter referred to as observation light) of light irradiated on a body tissue which is an observation target is condensed by the optical system and introduced into the image pickup element. In the image pickup unit 10112, the incident observation light is photoelectrically converted by the image pickup element, by which an image signal corresponding to the observation light is generated. The image signal generated by the image pickup unit 10112 is provided to the image processing unit 10113.

The image processing unit 10113 includes a processor such as a central processing unit (CPU) or a graphics processing unit (GPU) and performs various signal processes for an image signal generated by the image pickup unit 10112. The image processing unit 10113 provides the image signal for which the signal processes have been performed thereby as RAW data to the wireless communication unit 10114.

The wireless communication unit 10114 performs a predetermined process such as a modulation process for the image signal for which the signal processes have been performed by the image processing unit 10113 and transmits the resulting image signal to the external controlling apparatus 10200 through an antenna 10114A. Further, the wireless communication unit 10114 receives a control signal relating to driving control of the capsule type endoscope 10100 from the external controlling apparatus 10200 through the antenna 10114A. The wireless communication unit 10114 provides the control signal received from the external controlling apparatus 10200 to the control unit 10117.

The power feeding unit 10115 includes an antenna coil for power reception, a power regeneration circuit for regenerating electric power from current generated in the antenna coil, a voltage booster circuit and so forth. The power feeding unit 10115 generates electric power using the principle of non-contact charging.

The power supply unit 10116 includes a secondary battery and stores electric power generated by the power feeding unit 10115. In FIG. 14, in order to avoid complicated illustration, an arrow mark indicative of a supply destination of electric power from the power supply unit 10116 and so forth are omitted. However, electric power stored in the power supply unit 10116 is supplied to and can be used to drive the light source unit 10111, the image pickup unit 10112, the image processing unit 10113, the wireless communication unit 10114 and the control unit 10117.

The control unit 10117 includes a processor such as a CPU and suitably controls driving of the light source unit 10111, the image pickup unit 10112, the image processing unit 10113, the wireless communication unit 10114 and the power feeding unit 10115 in accordance with a control signal transmitted thereto from the external controlling apparatus 10200.

The external controlling apparatus 10200 includes a processor such as a CPU or a GPU, a microcomputer, a control board or the like in which a processor and a storage element such as a memory are mixedly incorporated. The external controlling apparatus 10200 transmits a control signal to the control unit 10117 of the capsule type endoscope 10100 through an antenna 10200A to control operation of the capsule type endoscope 10100. In the capsule type endoscope 10100, an irradiation condition of light upon an observation target of the light source unit 10111 can be changed, for example, in accordance with a control signal from the external controlling apparatus 10200. Further, an image pickup condition (for example, a frame rate, an exposure value or the like of the image pickup unit 10112) can be changed in accordance with a control signal from the external controlling apparatus 10200. Further, the substance of processing by the image processing unit 10113 or a condition for transmitting an image signal from the wireless communication unit 10114 (for example, a transmission interval, a transmission image number or the like) may be changed in accordance with a control signal from the external controlling apparatus 10200.

Further, the external controlling apparatus 10200 performs various image processes for an image signal transmitted thereto from the capsule type endoscope 10100 to generate image data for displaying a picked up in-vivo image on the display apparatus. As the image processes, various signal processes can be performed such as, for example, a development process (demosaic process), an image quality improving process (bandwidth enhancement process, a super-resolution process, a noise reduction (NR) process and/or image stabilization process) and/or an enlargement process (electronic zooming process). The external controlling apparatus 10200 controls driving of the display apparatus to cause the display apparatus to display a picked up in-vivo image on the basis of generated image data. Alternatively, the external controlling apparatus 10200 may also control a recording apparatus (not depicted) to record generated image data or control a printing apparatus (not depicted) to output generated image data by printing.

The description has been given above of one example of the in-vivo information acquisition system, to which the technology according to an embodiment of the present disclosure is applicable. The technology according to an embodiment of the present disclosure is applicable to, for example, the image pickup unit 10112 of the configurations described above. This makes it possible to improve detection accuracy.

### Application Example 4

### <Example of Practical Application to Endoscopic Surgery System>

The technology according to an embodiment of the present disclosure (present technology) is applicable to various products. For example, the technology according to an embodiment of the present disclosure may be applied to an endoscopic surgery system.

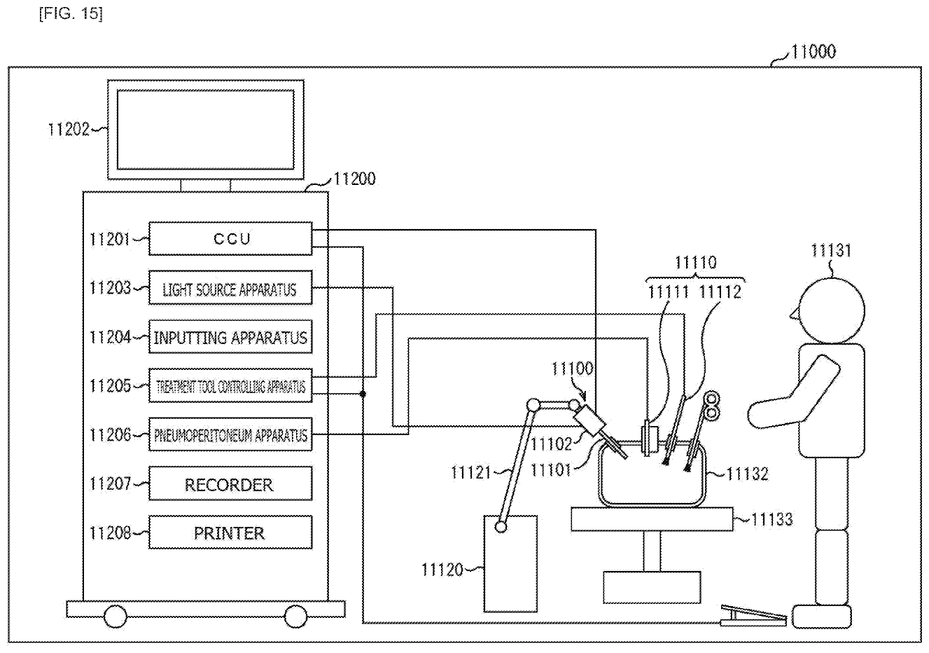

FIG. 15 is a view depicting an example of a schematic configuration of an endoscopic surgery system to which the technology according to an embodiment of the present disclosure (present technology) can be applied.

In FIG. 15, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

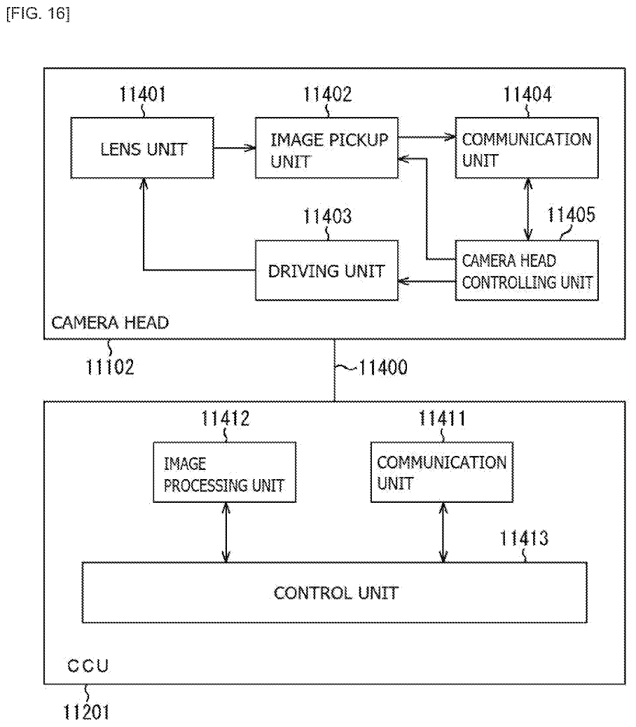

FIG. 16 is a block diagram depicting an example of a functional configuration of the camera head 11102 and the CCU 11201 depicted in FIG. 15.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given above of one example of the endoscopic surgery system, to which the technology according to an embodiment of the present disclosure is applicable. The technology according to an embodiment of the present disclosure is applicable to, for example, the image pickup unit 11402 of the configurations described above. Applying the technology according to an embodiment of the present disclosure to the image pickup unit 11402 makes it possible to improve detection accuracy.

It is to be noted that although the endoscopic surgery system has been described as an example here, the technology according to an embodiment of the present disclosure may also be applied to, for example, a microscopic surgery system, and the like.

### Application Example 5

### <Example of Practical Application to Mobile Body>

The technology according to an embodiment of the present disclosure (present technology) is applicable to various products. For example, the technology according to an embodiment of the present disclosure may be achieved in the form of an apparatus to be mounted to a mobile body of any kind. Non-limiting examples of the mobile body may include an automobile, an electric vehicle, a hybrid electric vehicle, a motorcycle, a bicycle, any personal mobility device, an airplane, an unmanned aerial vehicle (drone), a vessel, a robot, a construction machine, and an agricultural machine (tractor).

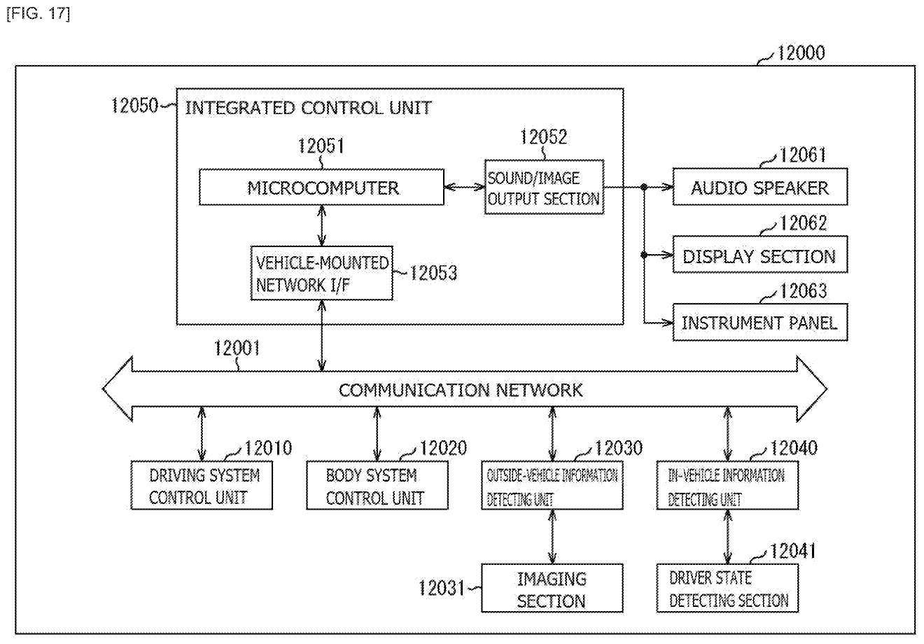

FIG. 17 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 17, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 17, an audio speaker 12061, a display section 12062, and an instrument panel 12063 are illustrated as the output device. The display section 12062 may, for example, include at least one of an on-board display and a head-up display.

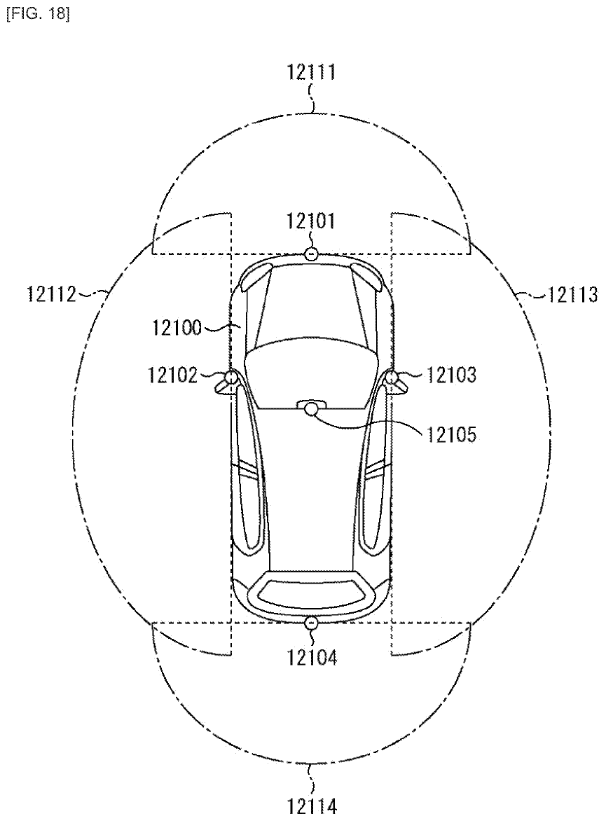

FIG. 18 is a diagram depicting an example of the installation position of the imaging section 12031.

In FIG. 18, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 18 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

Although the description has been given hereinabove referring to the embodiment and the modification examples, the content of the present disclosure is not limited to the foregoing embodiment, etc. and may be modified in a wide variety of ways.

It is to be noted that the effects described herein are merely exemplary and not limitative, and may include other effects.

It is to be noted that the present disclosure may also have the following configurations.

(1)

An imaging element including:

a sensor substrate having a light-receiving region in which a plurality of light-receiving elements are arranged and a peripheral region provided around the light-receiving region;

a sealing member disposed to be opposed to one surface of the sensor substrate;

a resin layer that attaches the sensor substrate and the sealing member to each other; and

an excavated part provided in the peripheral region of the one surface of the sensor substrate, and in which the resin layer is embedded,

the resin layer having one or a plurality of gaps inside the excavated part in a plan view.

(2)

The imaging element according to (1), in which the resin layer has a nanobubble structure as the gaps.

(3)

The imaging element according to (1), in which the resin layer has a microbubble structure as the gaps.

(4)

The imaging element according to any one of (1) to (3), in which the gaps are provided in at least one of an inside of the excavated part or a region above the excavated part.

(5)

The imaging element according to any one of (1) to (4), in which the sealing member has light-transmissivity.

(6)

The imaging element according to any one of (1) to (5), in which the resin layer is formed using at least one of an acrylic-based resin material, a styrene-based resin material, or an epoxy resin material.

(7)

The imaging element according to any one of (1) to (6), in which the sensor substrate has another surface opposed to the one surface and includes a multilayer wiring layer on the other surface.

(8)

An electronic apparatus including an imaging element,

the imaging element including

a sensor substrate having a light-receiving region in which a plurality of light-receiving elements are arranged and a peripheral region provided around the light-receiving region,

a sealing member disposed to be opposed to one surface of the sensor substrate,

a resin layer that attaches the sensor substrate and the sealing member to each other, and

an excavated part provided in the peripheral region of the one surface of the sensor substrate, and in which the resin layer is embedded,

the resin layer having one or a plurality of gaps inside the excavated part in a plan view.

This application claims the benefit of Japanese Priority Patent Application JP2018-136049 filed with the Japan Patent Office on Jul. 19, 2018, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. An imaging element comprising:
a sensor substrate having a light-receiving region in which a plurality of light-receiving elements are arranged and a peripheral region provided around the light-receiving region;
a sealing member disposed to be opposed to one surface of the sensor substrate;
a resin layer that attaches the sensor substrate and the sealing member to each other; and
an excavated part provided in the peripheral region of the one surface of the sensor substrate, and in which the resin layer is embedded,
the resin layer having one or a plurality of gaps inside the excavated part in a plan view.

2. The imaging element according to claim 1, wherein the resin layer has a nanobubble structure as the gaps.

3. The imaging element according to claim 1, wherein the resin layer has a microbubble structure as the gaps.

4. The imaging element according to claim 1, wherein the gaps are provided in at least one of an inside of the excavated part or a region above the excavated part.

5. The imaging element according to claim 1, wherein the sealing member has light-transmissivity.

6. The imaging element according to claim 1, wherein the resin layer is formed using at least one of an acrylic-based resin material, a styrene-based resin material, or an epoxy resin material.

7. The imaging element according to claim 1, wherein the sensor substrate has another surface opposed to the one surface and includes a multilayer wiring layer on the other surface.

8. An electronic apparatus comprising an imaging element,
the imaging element including
a sensor substrate having a light-receiving region in which a plurality of light-receiving elements are arranged and a peripheral region provided around the light-receiving region,
a sealing member disposed to be opposed to one surface of the sensor substrate,
a resin layer that attaches the sensor substrate and the sealing member to each other, and
an excavated part provided in the peripheral region of the one surface of the sensor substrate, and in which the resin layer is embedded,
the resin layer having one or a plurality of gaps inside the excavated part in a plan view.
